(19) United States
(12) Patent Application Publication
(10) Pub. No.: US 2025/0110338 A1
(43) Pub. Date: Apr. 3, 2025

(54) VIRTUAL REALITY DISPLAY SUN DAMAGE MITIGATION

(71) Applicant: Meta Platforms Technologies, LLC, Menlo Park, CA (US)

(72) Inventors: Jie LUO, Fremont, CA (US); Xinyu ZHU, San Jose, CA (US); Jie XIANG, San Jose, CA (US); Sandeep REKHI, San Jose, CA (US)

(21) Appl. No.: 18/882,643

(22) Filed: Sep. 11, 2024

Related U.S. Application Data
(60) Provisional application No. 63/586,343, filed on Sep. 28, 2023.

(51) Int. Cl. G02B 27/01; G02F 1/1333; G02F 1/1335; G02F 1/13363; H10K 59/80

(52) U.S. Cl. CPC G02B 27/0172; G02F 1/133311; G02F 1/133331; G02F 1/133512; G02F 1/133521; G02F 1/133531; G02F 1/133536; G02F 1/133548; G02F 1/133562; G02F 1/133638; G02B 2027/0178; G02F 2201/086; G02F 2201/501; H10K 59/8792

(57) ABSTRACT

A near-eye display includes a display panel (e.g., a liquid crystal display (LCD) panel or organic light emitting diode (OLED) display panel) configured to generate a display image, and display optics configured to project the display image to a user. The near-eye display also includes an optical attenuation layer formed on the display optics, between the display optics and the display panel and spaced apart from the display panel, or on a side of the display optics opposing the display panel. The optical attenuation layer includes, for example, a polarization film, an infrared (IR) blocking coating, an IR blocking optically clear adhesive layer, a photochromic (or UV blocking) coating, or a combination thereof. In some examples, the optical attenuation layer is formed on an accessory device (e.g., a prescription lens or a lens cover) of the near-eye display.

### CROSS-REFERENCE TO RELATED APPLICATION

This application claims the benefit of and priority to U.S. Provisional Application No. 63/586,343, filed Sep. 28, 2023, entitled “VIRTUAL REALITY DISPLAY SUN DAMAGE MITIGATION,” which is hereby incorporated by reference in its entirety for all purposes.

### BACKGROUND

An artificial reality system, such as a head-mounted display (HMD) or heads-up display (HUD) system, generally includes a near-eye display system in the form of a headset or a pair of glasses and configured to present content to a user via an electronic or optic display within, for example, about 10-20 mm in front of the user's eyes. The near-eye display system may display virtual objects or combine images of real objects with virtual objects, as in virtual reality (VR), augmented reality (AR), or mixed reality (MR) applications. A near-eye display generally includes an optical system configured to form an image of a computer-generated image on an image plane. The optical system of the near-eye display may relay the image generated by an image source (e.g., a display panel) to create a virtual image that appears to be away from the image source and further than just a few centimeters away from the user's eyes.

### SUMMARY

This disclosure relates generally to near-eye display systems. More specifically, and without limitation, techniques disclosed herein relate to mitigating damages of near-eye display systems (e.g., liquid crystal display-based near-eye display systems) caused by ambient light sources such as the sun. Various inventive embodiments are described herein, including devices, systems, methods, structures, materials, processes, and the like.

According to certain embodiments, the front polarizer of a liquid crystal display (LCD) panel in a near-eye display may be moved to a location before the bright ambient light (e.g., sunlight) is focused into a high-intensity spot, or an additional polarizer may be added to a near-eye display at a location before the bright ambient light may be focused into a high-intensity spot. In this way, about a half of the ambient light may be blocked (reflected or absorbed) by the polarizer, and the intensity of the unfocused ambient light may not be too high to cause damages to the polarizer. As such, at the focal plane, the intensity of the focused ambient light may be significantly reduced to reduce or avoid damages to the display panel. The polarizer may include a supporting structure (e.g., a substrate) or may be a film that may be formed (e.g., coated or laminated) on an existing structure of the near-eye display, such as a lens, a cover window, a lens adaptor/cover, and the like. In some embodiments, additional coating layers, such as IR blocking coatings, IR blocking optically clear adhesive layers, photochromic (or UV blocking) coatings, or other optical attenuation films, may be formed on a structure (e.g., lens or polarizer) of the near-eye display. In some embodiments, the polarizer may be non-absorptive (e.g., reflective) such that the polarizer may be less likely to be damaged.

According to certain embodiments, a near-eye display system may include a liquid crystal display (LCD) panel configured to generate a display image, and display optics configured to project the display image to a user. The LCD panel may include a backlight unit configured to emit visible light; a first linear polarizer configured to linearly polarize the visible light emitted by the backlight unit; and a liquid crystal cell. The near-eye display system may also include a second linear polarizer that is formed on the display optics, between the display optics and the LCD panel and spaced apart from the LCD panel, or on a side of the display optics opposing the LCD panel. A transmission axis of the second linear polarizer may be parallel to a transmission axis of the first linear polarizer.

Techniques disclosed herein may also be used in other types of near-eye display systems. For example, the polarization film, IR blocking coating, IR blocking optically clear adhesive layer, photochromic (or UV blocking) coating, another optical attenuation film, or any combination thereof may be used in OLED-based near-eye display systems to reduce sun damage. In some embodiments, the polarization film, IR blocking coating, IR blocking optically clear adhesive layer, photochromic (or UV blocking) coating, another optical attenuation film, or any combination thereof may be used in an accessory device of a near-eye display, such as a prescription lens used in a near-eye display.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 is a cross-sectional view of an example of a near-eye display according to certain embodiments.

FIG. 5 illustrates an example of an optical system with a non-pupil forming configuration for a near-eye display device according to certain embodiments.

FIG. 6 illustrates an example of a liquid crystal display (LCD) panel.

FIG. 7 illustrates an example of a layer stack of an LCD panel.

FIG. 8 illustrates an example of damages to an LCD display panel of a near-eye display by sun light.

FIGS. 9A-9B illustrate examples of damages to LCD display panels of near-eye displays.

FIG. 10A illustrates an example of a structure of a near-eye display system.

FIG. 10B illustrates an example of a near-eye display system that may reduce or avoid damages to the LCD display panel by bright ambient light according to certain embodiments.

FIG. 10C illustrates another example of a near-eye display system that may reduce or avoid damages to the LCD display panel by bright ambient light according to certain embodiments.

FIGS. 11A-11C illustrate examples of near-eye display systems including L films for avoiding damages to display panels by bright ambient light according to certain embodiments.

FIGS. 12A-12C illustrate examples of near-eye display systems including linear polarizers coupled to display optics to avoid damages to display panels by bright ambient light according to certain embodiments.

FIGS. 13A-13C illustrate examples of near-eye display systems including linear polarizers between display optics and display panels to avoid damages to display panels by bright ambient light according to certain embodiments.

FIG. 14 illustrates an example of a near-eye display system including an L film on a cover window for avoiding damages to a display panel by bright ambient light according to certain embodiments.

FIGS. 15A-15B illustrate examples of using L films and/or infrared blocking layers to avoid damages to display panels by bright ambient light according to certain embodiments.

FIGS. 16A-16D illustrate examples of using photochromic coatings to avoid damages to display panels by bright ambient light according to certain embodiments.

FIG. 17 illustrates an example of a near-eye display system including a reflective linear polarizer to avoid damages to a display panel by bright ambient light according to certain embodiments.

FIGS. 18A-18C illustrate an example of reducing damages to a display panel of a near-eye display system by bright ambient light using techniques disclosed herein according to certain embodiments.

FIG. 19 illustrates an example of a micro-OLED display that may implement some of the examples disclosed herein according to certain embodiments.

FIG. 20 illustrate an example of a prescription lens that may implement some of the examples disclosed herein according to certain embodiments.

FIG. 21 is a simplified block diagram of an example of an electronic system of an example near-eye display (e.g., HMD device) for implementing some examples disclosed herein.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to near-eye display systems. More specifically, and without limitation, techniques disclosed herein relate to mitigating damages of near-eye display systems (e.g., liquid crystal display-based near-eye display systems) caused by ambient light sources such as the sun. Various inventive embodiments are described herein, including devices, systems, methods, structures, materials, processes, and the like.

Near-eye displays may generally include display panels or other images sources and display optics (e.g., lenses) that may project images generated by the display panels or other images sources to user's eyes. The display panels or other image sources may be implemented using, for example, liquid crystal display (LCD), organic light emitting diode (OLED) display, micro-OLED display, inorganic light emitting diode (ILED) display, quantum-dot light emitting diode (QLED) display, micro-light emitting diode (micro-LED) display, active-matrix OLED display (AMOLED), transparent OLED display (TOLED), and the like. It is generally desirable that the image source or the display panel of a near-eye display system has a higher resolution, a large color gamut, a large size, and better image quality, to improve the immersive experience of using the near-eye display system. For a battery-powered near-eye display system, it may also be desirable that the system has a higher power efficiency to improve the battery life of the system.

Many consumer virtual reality (VR) near-eye display systems use LCD panels to generate the displayed images. LCD panels for VR applications typically operate in a transmissive mode, where light may be modulated while being transmitted by the LCD panels. For example, a transmissive LCD panel may include a backlight unit (BLU) and a liquid crystal (LC) panel that may modulate and filter light from the BLU at individual pixels. The LC panel may include a liquid crystal cell sandwiched by a bottom (or back) substrate and a top (or front) substrate. In some implementations, the bottom substrate may include thin-film transistor (TFT) circuits formed on a glass substrate for controlling the liquid crystal cell, whereas the top substrate may include a common electrode and an array of color filters formed thereon. In some implementations, the bottom substrate may include both TFT circuits and an array of color filters formed on a glass substrate (referred to as color filter on array (COA)), whereas the top substrate may include a common electrode and a black matrix formed thereon. In some implementations, pixel electrodes and the common electrode may both be formed on the bottom substrate, for example, in fringe field switching (FFS) mode liquid crystal display, whereas the top substrate may include a black matrix and an overcoat layer formed thereon. LCD panels may offer many advantages over other display technologies, such as lower cost, longer lifetime, higher energy efficiencies, larger sizes, and the like.

In a near-eye display such as a virtual reality (VR) display, the display optics may be between the user's eyes and the display panel during use, and may be positioned such that the display panel may be on or near the focal plane of the display optics. Therefore, the display optics may collimate light from the display panel and convert spatial information of the displayed images into angular information. As such, the display optics may relay the images to create virtual images that appear to be far away from the display panel and further than just a few centimeters away from the eyes of the user. When is the near-eye display is not in use (e.g., not worn by a user), ambient light may be focused onto the display panel by the display optics. For example, when the display optics of a VR display is facing a bright ambient light source such as the sun, sunlight may be focused onto the display panel by the display optics. The focused sunlight may have very high intensity that may cause permanent damages to components of the display panel (e.g., polarizers, thin films, coatings, liquid crystal cells, etc.), in particular, the component at the peak intensity, such as the front polarizer of a liquid crystal display panel that is used to pass light in a particular polarization direction but at least partially block (e.g., absorb) light in other polarization directions.

According to certain embodiments disclosed herein, the front polarizer of an LCD panel in a near-eye display may be moved to a location before the bright ambient light (e.g., sunlight) is focused into a high-intensity spot, or an additional polarizer may be added to a near-eye display at a location before the bright ambient light may be focused into a high-intensity spot. In this way, about a half of the ambient light may be blocked (reflected or absorbed) by the polarizer, and the intensity of the unfocused ambient light may not be too high to cause damages to the polarizer. As such, at the focal plane, the intensity of the focused ambient light may be significantly reduced to reduce or avoid damages to the display panel. The polarizer may include a supporting structure (e.g., a substrate) or may be a film that may be formed (e.g., coated or laminated) on an existing structure of the near-eye display, such as a lens, a cover window, a lens adaptor/cover, and the like. In some embodiments, additional coating layers, such as IR blocking coatings, IR blocking optically clear adhesive layers, or photochromic (or UV blocking) coatings, may be formed on a structure (e.g., lens or polarizer) of the near-eye display. In some embodiments, the polarizer may be non-absorptive (e.g., reflective) such that the polarizer may be less likely to be damaged. Techniques disclosed herein, including the polarization films, IR blocking coatings, IR blocking optically clear adhesive layers, and photochromic (or UV blocking) coatings, may also be used in other near-eye display systems, such as OLED-based near-eye display systems and optics (e.g., prescription lenses).

Techniques described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through).

In the following description, for the purposes of explanation, specific details are set forth in order to provide a thorough understanding of examples of the disclosure. However, it will be apparent that myriad examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

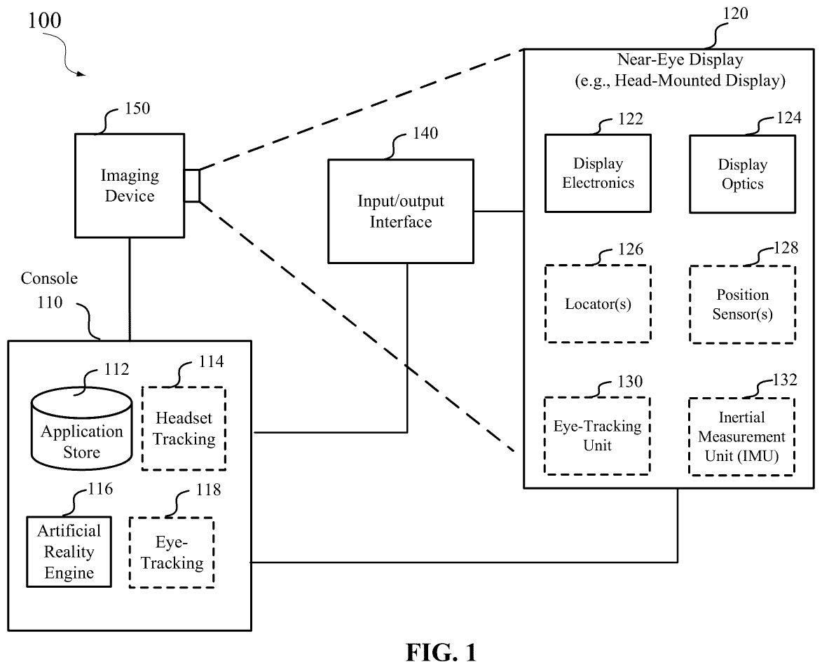

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

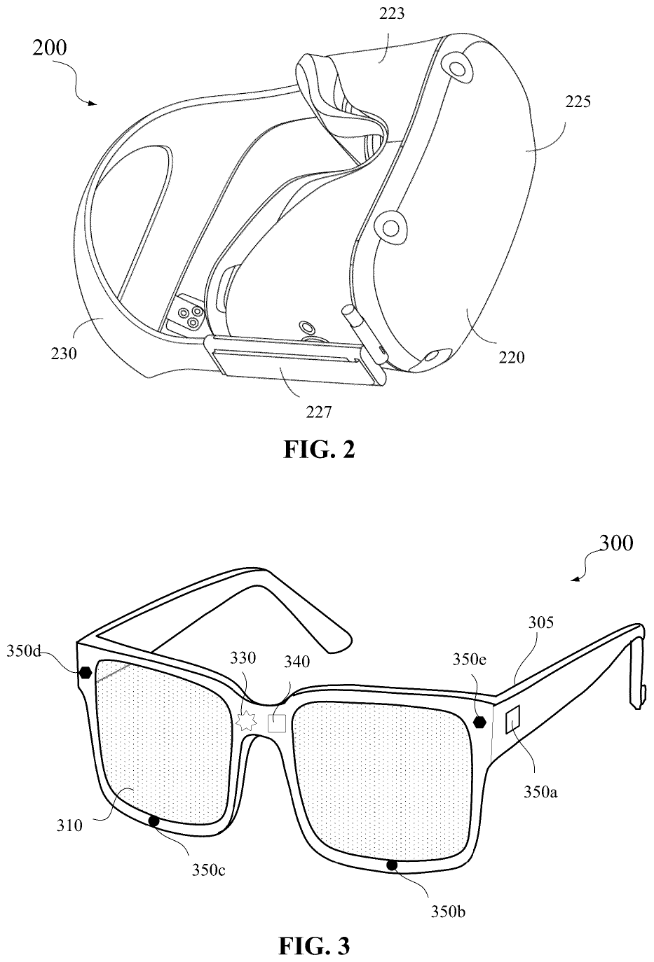

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to function as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light emitting diode (OLED) display, an inorganic light emitting diode (ILED) display, a micro light emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an antireflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be a light-emitting diode (LED), a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 12 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 120 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking subsystem 114, an artificial reality engine 116, and an eye-tracking subsystem 118. Some embodiments of console 110 may include different or additional devices or subsystems than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the devices or subsystems of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking subsystem 114 may track movements of near-eye display 120 using slow calibration information from external imaging device 150. For example, headset tracking subsystem 114 may determine positions of a reference point of near-eye display 120 using observed locators from the slow calibration information and a model of near-eye display 120. Headset tracking subsystem 114 may also determine positions of a reference point of near-eye display 120 using position information from the fast calibration information. Additionally, in some embodiments, headset tracking subsystem 114 may use portions of the fast calibration information, the slow calibration information, or any combination thereof, to predict a future location of near-eye display 120. Headset tracking subsystem 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking subsystem 114. Artificial reality engine 116 may also receive estimated eye position and orientation information from eye-tracking subsystem 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking subsystem 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking subsystem 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. High-resolution camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

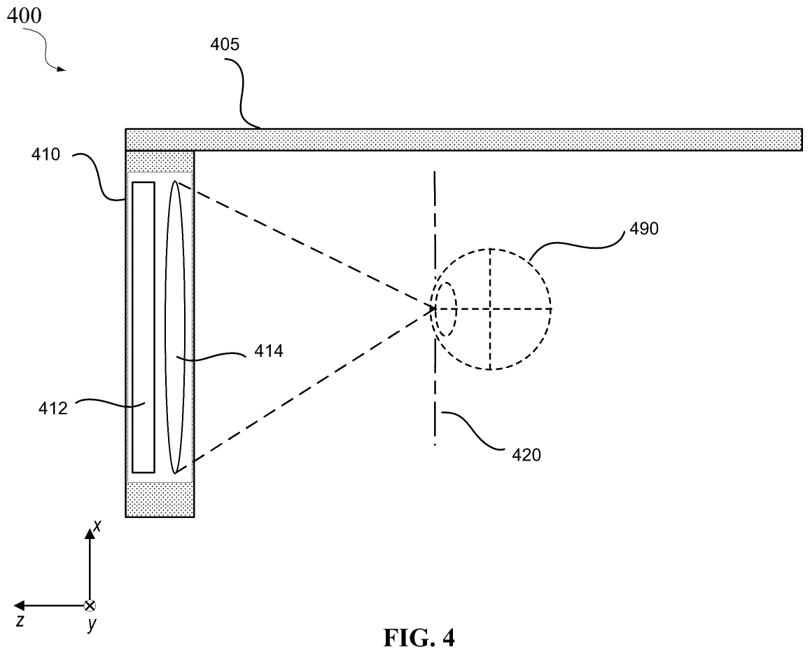

FIG. 4 is a cross-sectional view of an example of a near-eye display 400 according to certain embodiments. Near-eye display 400 may include at least one display assembly 410. Display assembly 410 may be configured to direct image light (e.g., display light) to an eyebox located at an exit pupil 420 and to user's eye 490. It is noted that, even though FIG. 4 and other figures in the present disclosure show an eye of a user of the near-eye display for illustration purposes, the eye of the user is not a part of the corresponding near-eye display.

As HMD device 200 and near-eye display 300, near-eye display 400 may include a frame 405 and display assembly 410 that may include a display 412 and/or display optics 414 coupled to or embedded in frame 405. As described above, display 412 may display images to the user electrically (e.g., using LCDs, LEDs, OLEDs) or optically (e.g., using a waveguide display and optical couplers) according to data received from a processing unit, such as console 110. In some embodiments, display 412 may include a display panel that includes pixels made of LCDs, LEDs, OLEDs, and the like. Display 412 may include sub-pixels to emit light of a predominant color, such as red, green, blue, white, or yellow. In some embodiments, display assembly 410 may include a stack of one or more waveguide displays including, but not restricted to, a stacked waveguide display, a varifocal waveguide display, and the like. The stacked waveguide display may be a polychromatic display (e.g., a red-green-blue (RGB) display) created by stacking waveguide displays whose respective monochromatic sources are of different colors.

Display optics 414 may be similar to display optics 124 and may display image content optically (e.g., using optical waveguides and optical couplers), correct optical errors associated with the image light, combine images of virtual objects and real objects, and present the corrected image light to exit pupil 420 of near-eye display 400, where the user's eye 490 may be located. In some embodiments, display optics 414 may also relay the images to create virtual images that appear to be away from display 412 and further than just a few centimeters away from the eyes of the user. For example, display optics 414 may collimate the image source to create a virtual image that may appear to be far away (e.g., greater than about 0.3 m, such as about 0.5 m, 1 m, or 3 m away) and convert spatial information of the displayed virtual objects into angular information. In some embodiments, display optics 414 may also magnify the source image to make the image appear larger than the actual size of the source image. More details of display 412 and display optics 414 are described below.

In various implementations, the optical system of a near-eye display, such as an HMD, may be pupil-forming or non-pupil-forming. Non-pupil-forming HMDs may not use intermediary optics to relay the displayed image, and thus the user's pupils may serve as the pupils of the HMD. Such non-pupil-forming displays may be variations of a magnifier (sometimes referred to as “simple eyepiece”), which may magnify a displayed image to form a virtual image at a greater distance from the eye. The non-pupil-forming display may use fewer optical elements. Pupil-forming HMDs may use optics similar to, for example, optics of a compound microscope or telescope, and may include some forms of projection optics that magnify an image and relay it to the exit pupil.

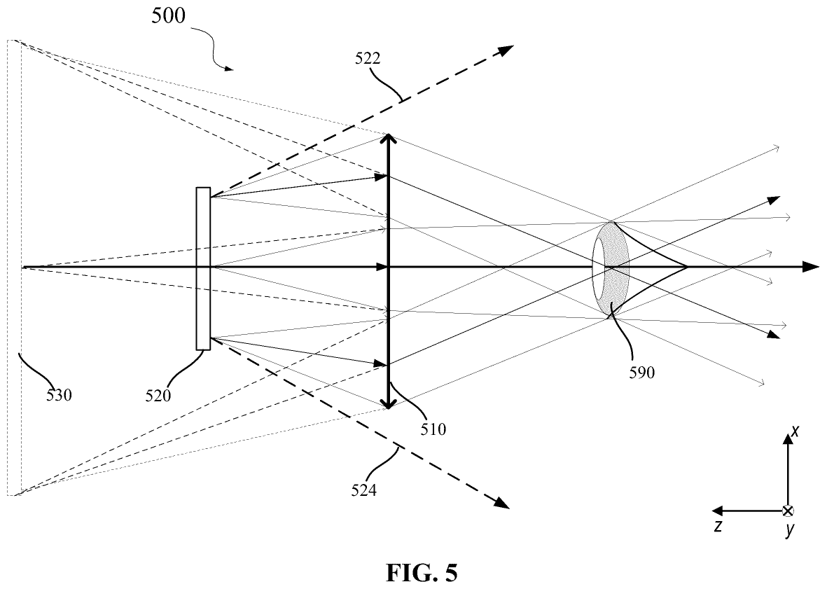

FIG. 5 illustrates an example of an optical system 500 with a non-pupil forming configuration for a near-eye display device according to certain embodiments. Optical system 500 may be an example of near-eye display 400, and may include display optics 510 and an image source 520 (e.g., a display panel). Display optics 510 may function as a magnifier. FIG. 5 shows that image source 520 is in front of display optics 510. In some other embodiments, image source 520 may be located outside of the field of view of the user's eye 590. For example, one or more deflectors or directional couplers may be used to deflect light from an image source to make the image source appear to be at the location of image source 520 shown in FIG. 5. Image source 520 may be an example of display 412 described above. For example, image source 520 may include a two-dimensional array of light emitters, such as semiconductor micro-LEDs or micro-OLEDs. The dimensions and pitches of the light emitters in image source 520 may be small. For example, each light emitter may have a diameter less than 2 μm (e.g., about 1.2 μm) and the pitch may be less than 2 μm (e.g., about 1.5 μm). As such, the number of light emitters in image source 520 can be equal to or greater than the number of pixels in a display image, such as 960×720, 1280×720, 1440×1080, 1920×1080, 2160×1080, 2560×1080, or even more pixels. Thus, a display image may be generated simultaneously by image source 520.

Light from an area (e.g., a pixel or a light emitter) of image source 520 may be directed to a user's eye 590 by display optics 510. Light directed by display optics 510 may form virtual images on an image plane 530. The location of image plane 530 may be determined based on the location of image source 520 and the focal length of display optics 510. A user's eye 590 may form a real image on the retina of user's eye 590 using light directed by display optics 510. In this way, objects at different spatial locations on image source 520 may appear to be objects on an image plane far away from user's eye 590 at different viewing angles. Image source 520 may have a size larger or smaller than the size (e.g., aperture) of display optics 510. Some light emitted from image source 520 with large emission angles (as shown by light rays 522 and 524) may not be collected and directed to user's eye 590 by display optics 510, and may become stray light.

The display panels or image sources described above (e.g., display 412 or image source 520) may be implemented using, for example, a liquid crystal display (LCD), an organic light emitting diode (OLED) display, a micro-OLED display, an inorganic light emitting diode (ILED) display, a micro-light emitting diode (micro-LED) display, an active-matrix OLED display (AMOLED), a transparent OLED display (TOLED), or some other displays. In a near-eye display system, it is generally desirable that the image source or the display panel has a higher resolution and a large size, such that the near-eye display system may have a large field of view (FOV) and better image quality to, for example, improve the immersive experience of using the near-eye display system. The FOV of a display system is the angular range over which an image may be projected in the near or far field. The FOV of a display system is generally measured in degrees, and the resolution over the FOV is generally measured in pixels per degree (PPD). The FOV of a display system may be linearly proportional to the size of the image source (e.g., the display panel), and may be inversely proportional to the focal length of the display optics (e.g., a collimation lens or lens assembly). A balance between the size of the image source and the optical power of the display optics may be needed in order to achieve a good modulation transfer function (MTF) and reduced size/weight/cost. The field of view may be increased by bringing the image source closer, but the image source would need to have higher PPD, and the aberrations of the display optics at the periphery may limit the effective field of view. To achieve a high PPD, micro displays with ultra-high pixels per inch (PPI) may be needed. There may be many technological challenges and cost issues associated with making high-PPI display panels, such as high resolution LCD panels.

Many consumer virtual reality (VR) near-eye display systems use LCD panels to generate the displayed images. LCD panels for VR applications typically operate in a transmissive mode, where light may be modulated while being transmitted by the LCD panels. For example, a transmissive LCD panel may include a backlight unit (BLU) and a liquid crystal (LC) panel that may modulate and filter light from the BLU at individual pixels. The LC panel may include a liquid crystal cell sandwiched by a bottom (or back) substrate and a top (or front) substrate. In some implementations, the bottom substrate may include thin-film transistor (TFT) circuits formed on a glass substrate for controlling the liquid crystal cell, whereas the top substrate may include a common electrode and an array of color filters formed thereon. In some implementations, the bottom substrate may include both TFT circuits and an array of color filters formed on a glass substrate (referred to as color filter on array (COA)), whereas the top substrate may include a common electrode and a black matrix formed thereon. In some implementations, pixel electrodes and the common electrode may both be formed on the bottom substrate, for example, in fringe field switching (FFS) mode liquid crystal display, whereas the top substrate may include a black matrix and an overcoat layer formed thereon.

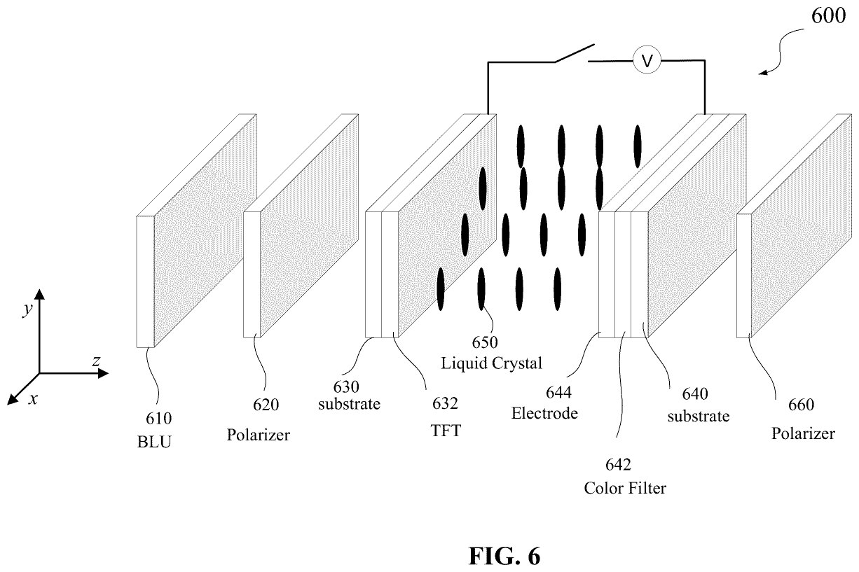

FIG. 6 illustrates an example of an LCD panel 600. As illustrated, LCD panel 600 may include a backlight unit (BLU) 610 configured to emit illumination light, a first polarizer 620 configured to control the type of light that can pass through (e.g., based on the polarization state of the light), an LCD cell that may modulate (e.g., the phase or polarization state of) the incident light, and a second polarizer 660 for control the type of light that can pass through (e.g., based on the polarization state of the light). In some embodiments, BLU 610 may include a light source (e.g., a cold-cathode fluorescent lamp) configured to emit white light. In some embodiments, BLU 610 may include blue light-emitting LEDs, a light guide plate, and a quantum dot film that includes quantum dots for converting some blue light to red light and green light.

In the illustrated example, the LCD cell may include a first substrate 630 (e.g., a glass substrate or another transparent dielectric substrate) including a thin-film transistor (TFT) array 632 formed thereon. TFT array 632 may include an array of transistors for controlling the intensity of each pixel (e.g., by controlling the orientations of the liquid crystal molecules in a liquid crystal layer, thereby controlling the rotation angle of the polarization direction of the incident light). The LCD cell may also include a second substrate 640 with a common electrode 644 and a color filter (CF)/black-matrix (BM) array 642 formed thereon. One or more liquid crystal layers 650 may be sandwiched by first substrate 630 and second substrate 640.

In some other implementations, first substrate 630 may include both TFT array 632 and color filters formed on TFT array 632 to form a color filter on array (COA) structure, whereas the top substrate may include a common electrode and a black matrix formed on another glass substrate. The COA structure may enable a simplified process, improved aperture ratio, and reduced production cost. In some implementations, the LCD cell may be a fringe field switching (FFS) mode LCD cell, where the pixel electrodes and the common electrode may both be formed on the bottom substrate, and the top substrate may include a black matrix and an overcoat layer formed thereon.

Light emitted by BLU 610 (e.g., white light or blue light) may be polarized by first polarizer 620 (e.g., a linear polarizer with a polarizing axis in a first direction). The polarized light may pass through an array of apertures between the TFTs in TFT array 632. The polarized light may be modulated by the one or more liquid crystal layers 650 to change the polarization state (e.g., the polarization direction) according to the voltage signal applied to each region of the one or more liquid crystal layers 650. CF/BM array 642 may include red, green, and blue color filters, where each color filter may allow light of one color to pass through. Light passing through each color filter may become a subpixel of a color image pixel that may include three subpixels, and may be filtered by second polarizer 660 such that the change in the polarization state may be converted into a change in the light intensity or brightness. For example, second polarizer 660 may include a linear polarizer with a polarizing axis in a second direction that may be the same as or different from the first direction. The transmission axis of first polarizer 620 may be aligned with the transmission axis of second polarizer 660.

FIG. 7 illustrates an example of a layer stack of an LCD panel 700. LCD panel 700 may be an example of LCD panel 600. In the illustrated example, LCD panel 700 may include a BLU 710, a first polarizer 720, a first substrate 730 including a TFT array and/or black-mask 732 and an array of apertures 734 formed thereon, a common electrode layer 735, a second substrate 740 with a CF/BM array including a black-matrix layer 742 and optionally an array of color filters 744 in black-matrix layer 742, and a second polarizer 750. BLU 710 may be similar to BLU 610 described above. TFT array and/or black-mask 732 may include TFT circuits (e.g., TFTs, gate electrodes, source electrodes, etc.) for controlling liquid crystal molecules filled between first substrate 730 and second substrate 740. Common electrode layer 735 may include a transparent conductive oxide (TCO), such as indium tin oxide (ITO). Color filters 744 may include red, green, and blue color filters. Centers of color filters 744 may align with corresponding centers of apertures 734 on first substrate 730, such that light from BLU 710 and first polarizer 720 may pass through apertures 734 and color filters 744. Second polarizer 750 may include a linear polarizer with a polarizing axis in a direction that is different from or same as the direction of the polarizing axis of first polarizer 720. For example, the direction of the polarizing axis of first polarizer 720 may be orthogonal to the direction of the polarizing axis of second polarizer 750. First polarizer 720 and second polarizer 750 may be used in combination to convert the change in the polarization state (e.g., polarization direction) by the liquid crystal layer to change in the light intensity so as to display images to user's eyes.

As described above with respect to FIG. 6, in some implementations, instead of forming color filters 744 on a separate substrate, color filters 744 may be formed on first substrate 730 (e.g., between TFT array and/or black-mask 732) to form a COA structure. In some implementations, the LCD cell may be an FFS mode LCD cell, where both the pixel electrodes and the common electrode may be formed on first substrate 730 that includes the TFT array and/or black-mask 732. In other implementations, the TFT array, the color filters, the black matrix, and the electrodes may be arranged in other manners on the two substrates that sandwich the liquid crystal material.

Even though not shown in FIG. 7, spacers (e.g., plastic spacers) may be used between TFT array and/or black-mask 732 and common electrode layer 735 to separate TFT array and/or black-mask 732 and common electrode layer 735 so that liquid crystal materials may be filled between TFT array and/or black-mask 732 (or a protective or planarization layer 736) and common electrode layer 735 to modulate incident light. For example, TFT array and/or black-mask 732 may include column spacers formed thereon (e.g., on top of source electrodes), and the CF/BM array (or black-matrix layer 742 or common electrode layer 735) may include photo spacers formed thereon. When first substrate 730 and second substrate 740 are assembled to form an LCD cell, photo spacers may sit on corresponding column spacers to achieve the desired separation between TFT array and/or black-mask 732 and the CF/BM array (or black-matrix layer 742 or common electrode layer 735).

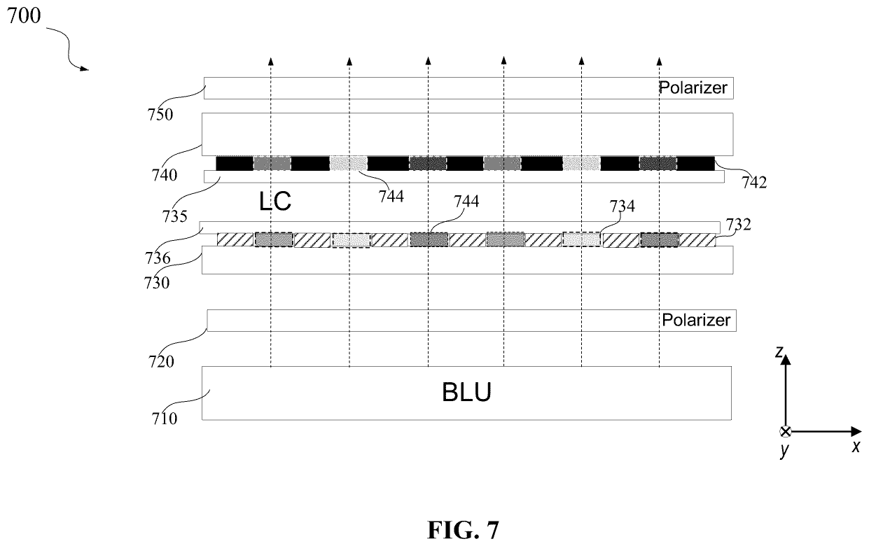

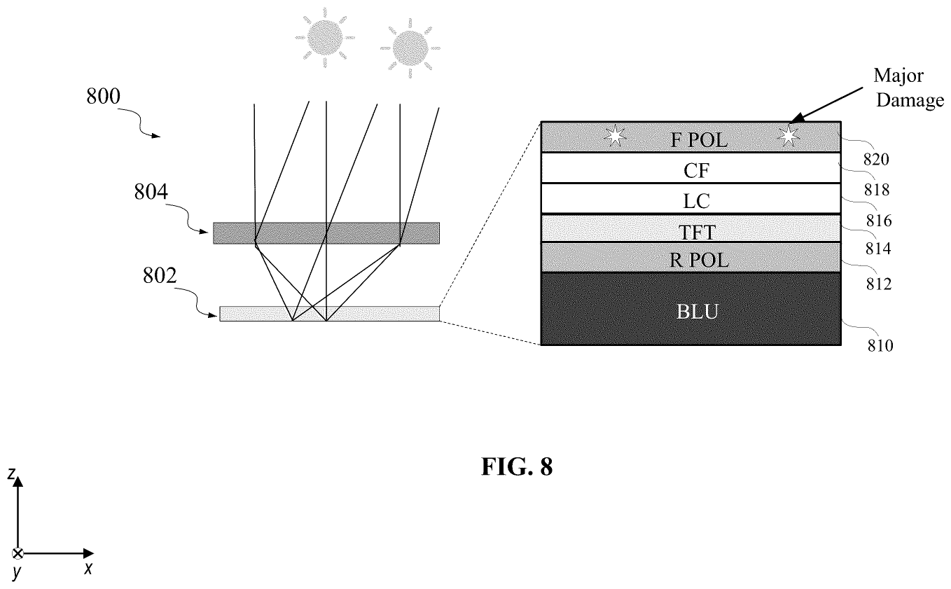

FIG. 8 illustrates an example of damages to an LCD display panel of a near-eye display 800 (e.g., a VR display) by sunlight. As described above with respect to, for example, FIGS. 4 and 5, near-eye display 800 may include a display panel 802 and display optics 804, where display panel 802 may be at or near a focal plane of display optics 804. In one example, display panel 802 may be an LCD display panel that includes, for example, a backlight unit 810, a rear polarizer 812 (e.g., first polarizer 620 or 720), a TFT layer 814, an LC cell 816, a color filter layer 818, and a front polarizer (e.g., second polarizer 660 or 750), as described above with respect to, for example, FIGS. 6 and 7. When near-eye display 800 is not in use, for example, when display optics 804 is facing an ambient light source such as the sun, display optics 804 may focus the sunlight onto display panel 802. At front polarizer 820, the focused sunlight may have high intensity and thus may damage (e.g., burn) front polarizer 820 due to high light absorption (e.g., about 50% for unpolarized light) by front polarizer 820 and heat accumulation at front polarizer 820.

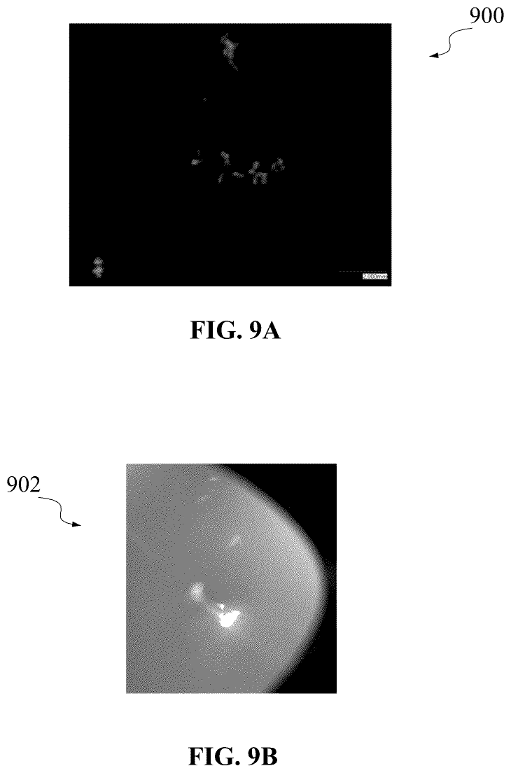

FIGS. 9A-9B illustrate examples of damages to LCD display panels of near-eye displays. Images 900 and 902 in FIGS. 9A and 9B show permanently damaged regions of examples of LCD display panels of near-eye display systems exposed to sunlight.

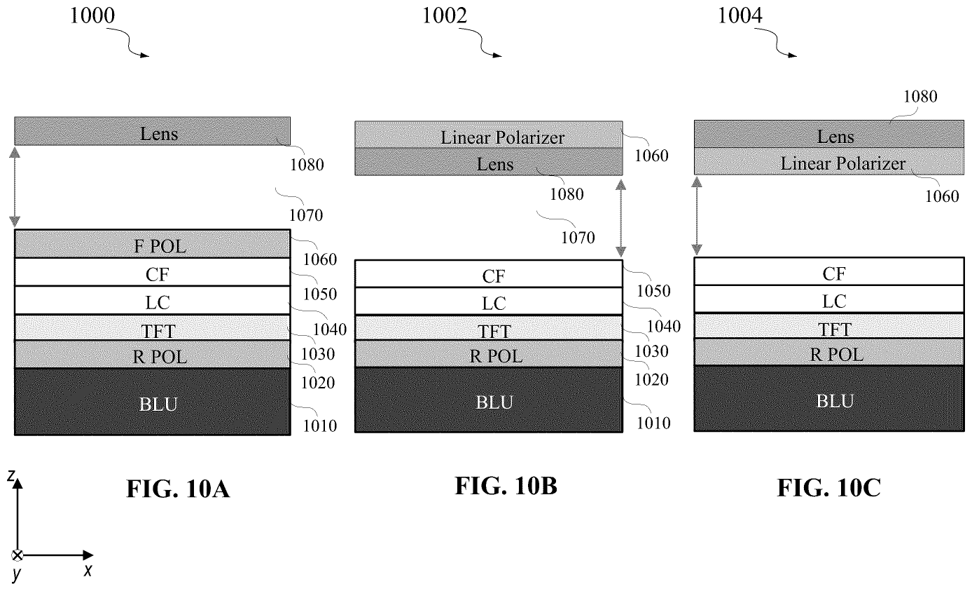

FIG. 10A illustrates an example of a structure of a near-eye display system 1000. In the illustrated example, near-eye display system 1000 may include an LCD display panel that may include a layer stack as described above with respect to FIGS. 6-7. For example, the display panel of near-eye display system 1000 may include a backlight unit 1010, a rear polarizer 1020, a TFT layer 1030, an LC cell 1040, a color filter layer 1050, and a front polarizer 1060. Front polarizer 1060 may be aligned with rear polarizer 1020. Display optics 1080 may include one or more lenses, such as a Fresnel lens. Display optics 1080 may be separated from the LCD display panel by a spacer 1070, such that the focal plane of display optics 1080 may be at or near the LCD display panel (e.g., LC cell 1040 and/or color filter layer 1050).

FIG. 10B illustrates an example of a near-eye display system 1002 that may reduce or avoid damages to the LCD display panel by bright ambient light according to certain embodiments. Near-eye display system 1002 may include the same or similar components as near-eye display system 1000, but the component of near-eye display system 1002 may have a different arrangement. For example, front polarizer 1060 may be moved to a location adjacent to display optics 1080, such as coupled to an outer surface of display optics 1080. In this arrangement, ambient light from, for example, the sun, may be filtered by front polarizer 1060 before the ambient light can be focused by display optics 1080. Thus, about 50% or more of the ambient light may be blocked and prevented from reaching other components of the display panel. Therefore, the intensity of the ambient light focused onto, for example, color filter layer 1050 (or second substrate 640 or 740) may only be a half or lower of the intensity of the ambient light focused onto front polarizer 1060 in near-eye display system 1000.

FIG. 10C illustrates another example of a near-eye display system 1004 that may reduce or avoid damages to the LCD display panel by bright ambient light according to certain embodiments. Near-eye display system 1004 may include the same or similar components as near-eye display system 1000, but the component of near-eye display system 1004 may have a different arrangement. For example, front polarizer 1060 may be moved to a location adjacent to display optics 1080, such as coupled to an inner surface of display optics 1080. In this arrangement, ambient light passing through display optics 1080 may be filtered by front polarizer 1060 before the ambient light modified by display optics 1080 is focused into a small, high-intensity light spot. Thus, about 50% or more of the ambient light may be blocked and prevented from reaching other components of the display panel. Therefore, the intensity of the ambient light focused onto, for example, color filter layer 1050 (or second substrate 640 or 740) may only be a half or lower of the intensity of the ambient light focused onto front polarizer 1060 in near-eye display system 1000.

Even though not shown in FIG. 10B or 10C, in some embodiments, front polarizer 1060 may be positioned in any location before the ambient light is focused into a small, high-intensity spot. In these embodiments and the embodiments shown in FIGS. 10B and 10C, no additional components are added but the damages to the display panel can be significantly reduced, compared with the structure shown in FIG. 10A.

In various embodiments, front polarizer 1060 and rear polarizer 1020 may be implemented using, for example, double refraction or birefringent polarizers, reflective polarizers, dichroic absorptive polarizers, and the like. For example, the polarizers may include birefringent crystals that can be configured to divide a single beam of unpolarized light into two separate polarized beams of equal intensity, or may include dichroic material that can absorb light polarized in a particular direction. For example, stretched polyvinyl alcohol (PVA) may be used as the dichroic material in dichroic polarizers. In some embodiments, front polarizer 1060 and rear polarizer 1020 may include a supporting structure such as a transparent substrate.

In some implementations, a linear polymer film (L film) polarizer may be coated or laminated on an existing component of a near-eye display, such as the display optics, a cover window, a lens adaptor, and the like, and may be used as a linear polarizer. The L film polarizer may include, for example, a PVA sheet that is stretched and dyed with iodine during the manufacturing process to allow light of only a single polarization orientation to be transmitted. Incident light of all other orientations may be blocked (e.g., absorbed in the case of dichroic polarizer). In some embodiments, the L film polarizer may be non-iodine based PVA absorptive polarizer. In some embodiments, reflective polarizer (rather than absorptive polarizer) such as wire grid reflective polarizer may be used.

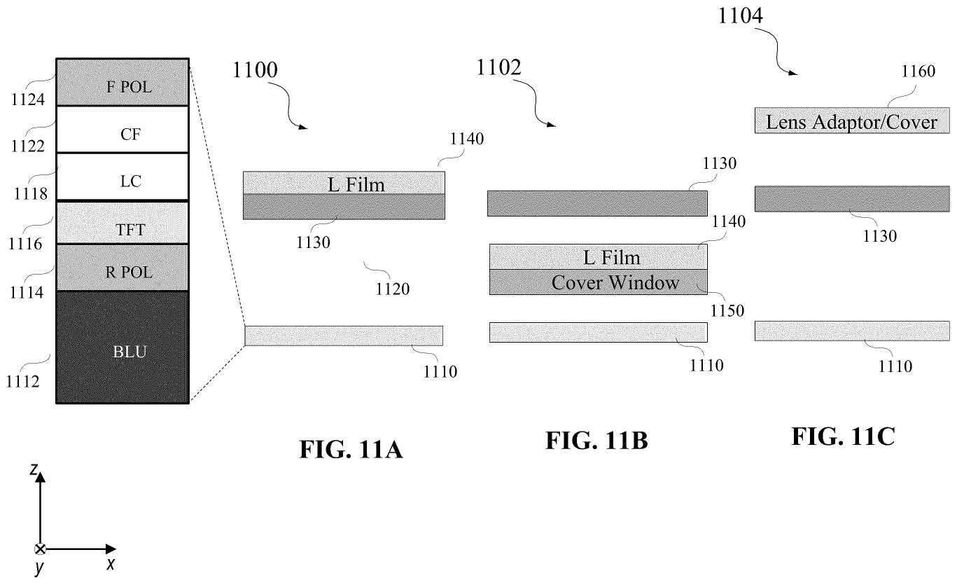

FIGS. 11A-11C illustrate examples of near-eye display systems including L films for avoiding damages to display panels by bright ambient light according to certain embodiments. In the example illustrated in FIG. 11A, a near-eye display system 1100 may include an LCD display panel 1110 that may include a layer stack as described above with respect to FIGS. 6, 7, 8, and 10A. For example, LCD display panel 1110 may include a backlight unit 1112, a rear polarizer 1114, a TFT layer 1116, an LC cell 1118, a color filter layer 1122, and a front polarizer 1124. Front polarizer 1124 may be aligned with rear polarizer 1114. Display optics 1130 may include one or more lenses, such as a Fresnel lens. Display optics 1130 may be separated from LCD display panel 1110 by a spacer 1120, such that the focal plane of display optics 1130 may be at or near LCD display panel 1110. An L film 1140 may be laminated on an outer surface of display optics 1130. Ambient light from, for example, the sun, may be filtered by L film 1140 before the ambient light can be focused by display optics 1130. L film 1140 may only allow light of a certain linear polarization state to pass through. Thus, about 50% or more of the ambient light (e.g., unpolarized light) may be blocked and prevented from reaching LCD display panel 1110. Therefore, the intensity of the ambient light focused onto LCD display panel 1110 (e.g., front polarizer 1124, color filter layer 1122, or LC cell 1118) may only be a half or lower of the intensity of the ambient light focused onto LCD display panel 1110 when L film 1140 is not used. The transmission axis of L film 1140 may align with the transmission axis of front polarizer 1124, such that the addition of L film 1140 may cause minimum or no additional loss of the display light from LCD display panel 1110 when near-eye display system 1100 is in normal operation. In addition, light passing through L film 1140 may be mostly transmitted and may not be absorbed by front polarizer 1124 because the polarization direction of the light aligns with the transmission axis of front polarizer 1124. Therefore, front polarizer 1124 may not be damaged by the ambient light. Even though FIG. 11A shows that L film 1140 may be laminated onto the outer surface of display optics 1130, in other embodiments, L film 1140 may be laminated onto the inner surface of display optics 1130.

In the example illustrated in FIG. 11B, a near-eye display system 1102 may include LCD display panel 1110 that may include a layer stack as described above with respect to FIG. 11A. Display optics 1130 may be separated from LCD display panel 1110 by one or more spacers, such that the focal plane of display optics 1130 may be at or near LCD display panel 1110. An L film 1140 may be laminated on a cover window 1150 that is between display optics 1130 and LCD display panel 1110. Ambient light from, for example, the sun, may be modified by display optics 1130 and filtered by L film 1140 before the ambient light is focused into a small, high-intensity spot onto LCD display panel 1110. L film 1140 may only allow light of a certain linear polarization state to pass through. Thus, about 50% or more of the ambient light (e.g., unpolarized light) may be blocked and prevented from reaching LCD display panel 1110. Therefore, the intensity of the ambient light focused onto LCD display panel 1110 (e.g., front polarizer 1124, color filter layer 1122, or LC cell 1118) may only be a half or lower of the intensity of the ambient light focused onto LCD display panel 1110 when L film 1140 is not used. The transmission axis of L film 1140 may align with the transmission axis of front polarizer 1124, such that the addition of L film 1140 may cause minimum or no additional loss of the display light from LCD display panel 1110 when near-eye display system 1100 is in normal operation. In addition, light passing through L film 1140 may be mostly transmitted and may not be absorbed by front polarizer 1124 because the polarization direction of the light aligns with the transmission axis of front polarizer 1124. Therefore, front polarizer 1124 may not be damaged by the ambient light. Even though FIG. 11B shows that L film 1140 may be laminated onto a surface of cover window 1150 facing display optics 1130, in other embodiments, L film 1140 may also be laminated onto a surface of cover window 1150 facing LCD display panel 1110.

In the example illustrated in FIG. 11C, a near-eye display system 1104 may include LCD display panel 1110 that may include a layer stack as described above with respect to FIG. 11A. Display optics 1130 may be separated from LCD display panel 1110 by a spacer, such that the focal plane of display optics 1130 may be at or near LCD display panel 1110. An L film may be laminated on or otherwise integrated into a lens adaptor 1160 (or lens cover) that is between display optics 1130 and the ambient environment. Ambient light from, for example, the sun, may be filtered by the L film before the ambient light can be focused by display optics 1130. The L film may only allow light of a certain linear polarization state to pass through. Thus, about 50% or more of the ambient light (e.g., unpolarized light) may be blocked and prevented from reaching LCD display panel 1110. Therefore, the intensity of the ambient light focused onto LCD display panel 1110 (e.g., front polarizer 1124, color filter layer 1122, or LC cell 1118) may only be a half or lower of the intensity of the ambient light focused onto LCD display panel 1110 when the L film is not used. The transmission axis of the L film may align with the transmission axis of front polarizer 1124, such that the addition of the L film may cause minimum or no additional loss of the display light from LCD display panel 1110 when near-eye display system 1100 is in normal operation. In addition, light passing through the L film may be mostly transmitted and may not be absorbed by front polarizer 1124 because the polarization direction of the light aligns with the transmission axis of front polarizer 1124. Therefore, front polarizer 1124 may not be damaged by the ambient light.

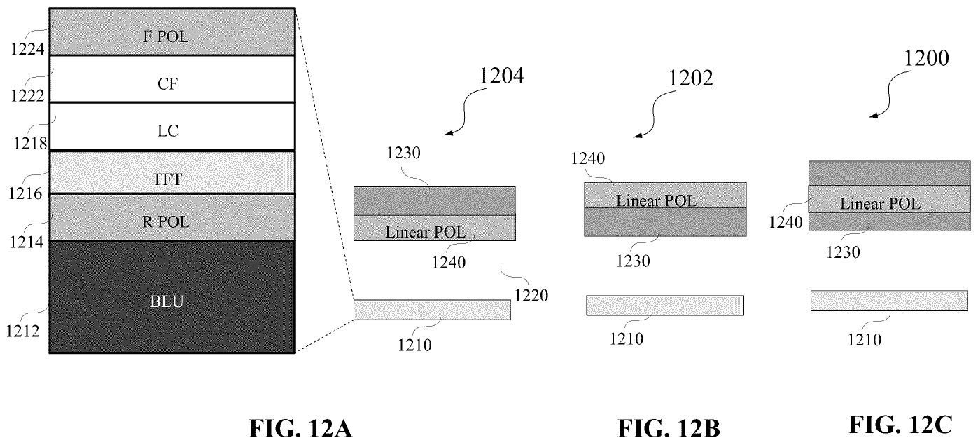

FIGS. 12A-12C illustrate examples of near-eye display systems including linear polarizers coupled to display optics to avoid damages to display panels by bright ambient light according to certain embodiments. In the example illustrated in FIG. 12A, a near-eye display system 1200 may include an LCD display panel 1210 that may include a layer stack as described above with respect to FIG. 11A. For example, LCD display panel 1210 may include a backlight unit 1212, a rear polarizer 1214, a TFT layer 1216, an LC cell 1218, a color filter layer 1222, and a front polarizer 1224. Front polarizer 1224 may be aligned with rear polarizer 1214. Display optics 1230 may include one or more lenses, such as a Fresnel lens. Display optics 1230 may be separated from LCD display panel 1210 by a spacer 1220, such that the focal plane of display optics 1230 may be at or near LCD display panel 1210. A linear polarizer 1240 may be positioned next to display optics 1230, such as coupled to an inner side of display optics 1230 facing LCD display panel 1210. Ambient light from, for example, the sun, may be modified by display optics 1230 and filtered by linear polarizer 1240 before the ambient light is focused into a high-intensity spot. Linear polarizer 1240 may only allow light of a certain linear polarization state to pass through. Thus, about 50% or more of the ambient light (e.g., unpolarized light) may be blocked and prevented from reaching LCD display panel 1210. Therefore, the intensity of the ambient light focused onto LCD display panel 1210 (e.g., front polarizer 1224, color filter layer 1222, or LC cell 1218) may only be a half or lower of the intensity of the ambient light focused onto LCD display panel 1210 when linear polarizer 1240 is not used. The transmission axis of linear polarizer 1240 may align with the transmission axis of front polarizer 1224, such that the addition of linear polarizer 1240 may cause minimum or no additional loss of the display light from LCD display panel 1210 when near-eye display system 1200 is in normal operation. In addition, light passing through linear polarizer 1240 may be mostly transmitted and may not be absorbed by front polarizer 1224 because the polarization direction of the light aligns with the transmission axis of front polarizer 1224. Therefore, front polarizer 1224 may not be damaged by the ambient light.

In the example illustrated in FIG. 12B, a near-eye display system 1202 may be similar to near-eye display system 1200 of FIG. 12A, and may include linear polarizer 1240 coupled to an outer side of display optics 1230 facing LCD display panel 1210. Ambient light from, for example, the sun, may be filtered by linear polarizer 1240 before the ambient light can be focused by display optics 1230. Linear polarizer 1240 may only allow light of a certain linear polarization state to pass through. Thus, about 50% or more of the ambient light (e.g., unpolarized light) may be blocked and prevented from reaching LCD display panel 1210. Therefore, the intensity of the ambient light focused onto LCD display panel 1210 (e.g., front polarizer 1224, color filter layer 1222, or LC cell 1218) may only be a half or lower of the intensity of the ambient light focused onto LCD display panel 1210 when linear polarizer 1240 is not used. The transmission axis of linear polarizer 1240 may align with the transmission axis of front polarizer 1224, such that the addition of linear polarizer 1240 may cause minimum or no additional loss of the display light from LCD display panel 1210 when near-eye display system 1202 is in normal operation. In addition, light passing through linear polarizer 1240 may be mostly transmitted and may not be absorbed by front polarizer 1224 because the polarization direction of the light aligns with the transmission axis of front polarizer 1224. Therefore, front polarizer 1224 may not be damaged by the ambient light.

In the example illustrated in FIG. 12C, a near-eye display system 1204 may be similar to near-eye display system 1200 of FIG. 12A, and may include linear polarizer 1240 within display optics 1230. For example, display optics 1230 may include two or more optical elements, and linear polarizer 1240 may be between the two or more elements. In one example, display optics 1230 may include a pancake lens. Ambient light from, for example, the sun, may be filtered by linear polarizer 1240 before the ambient light is focused into a high-intensity spot by display optics 1230. Linear polarizer 1240 may only allow light of a certain linear polarization state to pass through. Thus, about 50% or more of the ambient light (e.g., unpolarized light) may be blocked and prevented from reaching LCD display panel 1210. Therefore, the intensity of the ambient light focused onto LCD display panel 1210 (e.g., front polarizer 1224, color filter layer 1222, or LC cell 1218) may only be a half or lower of the intensity of the ambient light focused onto LCD display panel 1210 when linear polarizer 1240 is not used. The transmission axis of linear polarizer 1240 may align with the transmission axis of front polarizer 1224, such that the addition of linear polarizer 1240 may cause minimum or no additional loss of the display light from LCD display panel 1210 when near-eye display system 1204 is in normal operation. In addition, light passing through linear polarizer 1240 may be mostly transmitted and may not be absorbed by front polarizer 1224 because the polarization direction of the light aligns with the transmission axis of front polarizer 1224. Therefore, front polarizer 1224 may not be damaged by the ambient light.

In some implementations, to relax the requirement of aligning linear polarizer 1240 with front polarizer 1224, a pair of quarter wave plates may be used to convert linearly polarized light from front polarizer 1224 of LCD display panel 1210 (or from linear polarizer 1240) into circularly polarized light, and convert the circularly polarized light back to linearly polarized light that may pass through linear polarizer 1240 (or front polarizer 1224).

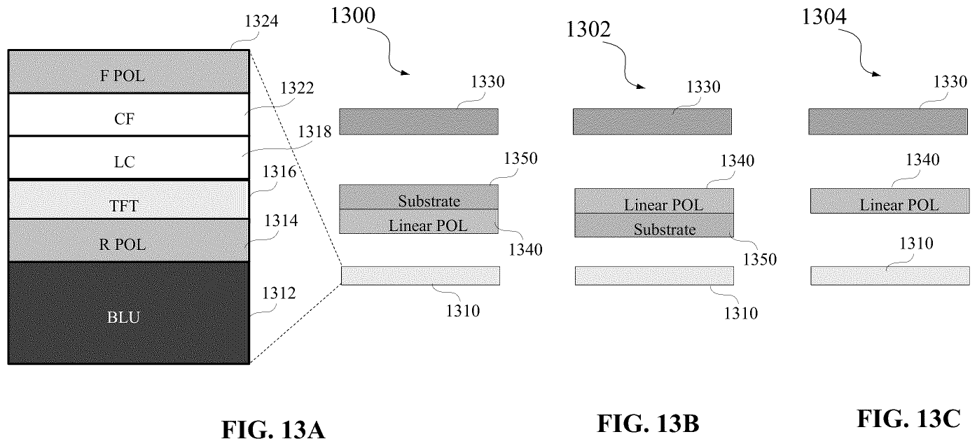

FIGS. 13A-13C illustrate examples of near-eye display systems including linear polarizers between display optics and display panels to avoid damages to the display panels by bright ambient light according to certain embodiments. In the examples illustrated in FIGS. 13A-13C, each of near-eye display systems 1300, 1302, and 1304 may include an LCD display panel 1310 that may include a layer stack as described above with respect to FIG. 12A. For example, LCD display panel 1310 may include a backlight unit 1312, a rear polarizer 1314, a TFT layer 1316, an LC cell 1318, a color filter layer 1322, and a front polarizer 1324. Front polarizer 1324 may be aligned with rear polarizer 1314. Display optics 1330 may include one or more lenses, such as a Fresnel lens. Display optics 1330 may be separated from LCD display panel 1310 by one or more spacers, such that the focal plane of display optics 1330 may be at or near LCD display panel 1310. A linear polarizer 1340 may be positioned between display optics 1330 and LCD display panel 1310. Linear polarizer 1340 may be coupled to either side of another structure 1350 (if any, such as a cover window) between display optics 1330 and LCD display panel 1310 as shown in FIGS. 13A and 13B, or may not be coupled to a structure between display optics 1330 and LCD display panel 1310 as shown in FIG. 13C. Ambient light from, for example, the sun, may be modified by display optics 1330 and filtered by linear polarizer 1340 before the ambient light is focused into a high-intensity spot. Linear polarizer 1340 may only allow light of a certain linear polarization state to pass through. Thus, about 50% or more of the ambient light (e.g., unpolarized light) may be blocked and prevented from reaching LCD display panel 1310. Therefore, the intensity of the ambient light focused onto LCD display panel 1310 (e.g., front polarizer 1324, color filter layer 1322, or LC cell 1318) may only be a half or lower of the intensity of the ambient light focused onto LCD display panel 1310 when linear polarizer 1340 is not used. The transmission axis of linear polarizer 1340 may align with the transmission axis of front polarizer 1324, such that the addition of linear polarizer 1340 may cause minimum or no additional loss of the display light from LCD display panel 1310 when near-eye display system 1300 is in normal operation. In addition, light passing through linear polarizer 1340 may be mostly transmitted and may not be absorbed by front polarizer 1324 because the polarization direction of the light aligns with the transmission axis of front polarizer 1324. Therefore, front polarizer 1324 may not be damaged by the ambient light.

In some implementations, to relax the requirement of aligning linear polarizer 1340 with front polarizer 1324, a pair of quarter wave plates may be used to convert linearly polarized light from front polarizer 1324 of LCD display panel 1310 (or from linear polarizer 1340) into circularly polarized light, and convert the circularly polarized light back to linearly polarized light that may pass through linear polarizer 1340 (or front polarizer 1324).

Even though not shown in FIGS. 12A-13C, in some embodiments, a linear polarizer (e.g., linear polarizer 1240 or 1340) may be coupled to a surface of a lens adaptor or a lens cover to block about a half of ambient light that may otherwise reach the LCD display. The transmission axis of the linear polarizer may align with the transmission axis of the front polarizer (e.g., front polarizer 1224 or 1324), such that the addition of the linear polarizer may cause minimum or no additional loss of the display light from the LCD display panel when the near-eye display is in normal operation. In addition, light passing through the linear polarizer may be mostly transmitted and may not be absorbed by the front polarizer because the polarization direction of the incident light aligns with the transmission axis of the front polarizer. Therefore, the front polarizer and other components of the LCD display panel may not be damaged by the ambient light.

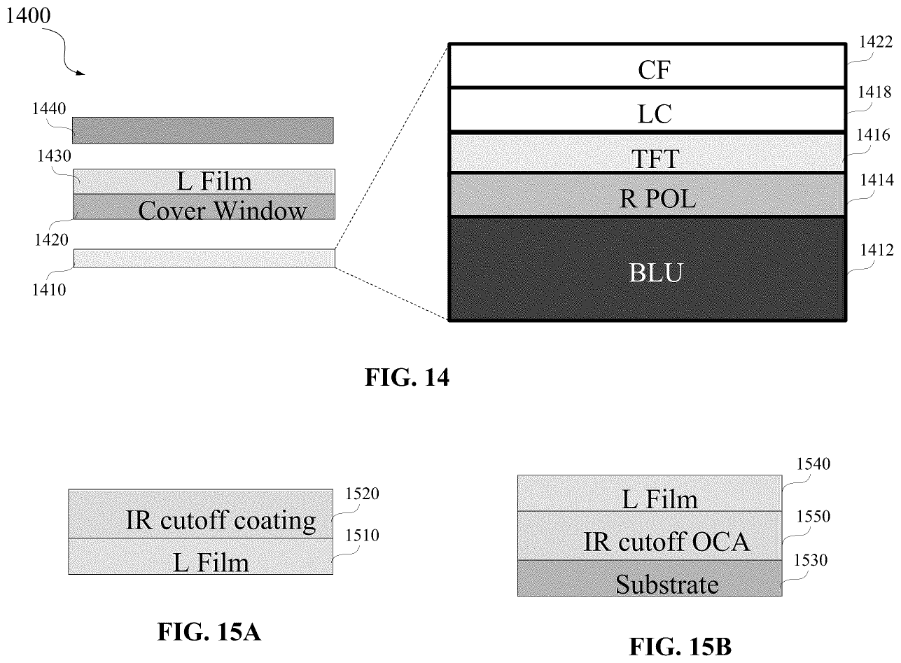

FIG. 14 illustrates an example of a near-eye display system 1400 including an L film 1430 on a cover window 1420 for avoiding damages to an LCD display panel 1410 by bright ambient light according to certain embodiments. LCD display panel 1410 may include a layer stack as described above. For example, LCD display panel 1410 may include a backlight unit 1412, a rear polarizer 1414, a TFT layer 1416, an LC cell 1418, and a color filter layer 1422. LCD display panel 1410 may not include a front polarizer. Near-eye display system 1400 may include a display optics 1440 that may include one or more lenses, such as a Fresnel lens. Display optics 1440 may be separated from LCD display panel 1410 by one or more spacers, such that the focal plane of display optics 1440 may be at or near LCD display panel 1410. L film 1430 may be laminated on a surface of cover window 1420 that is between display optics 1440 and LCD display panel 1410. The transmission axis of L film 1430 may align with the transmission axis of rear polarizer 1414. Ambient light from, for example, the sun, may be modified by display optics 1440 and may be filtered by L film 1430 before the ambient light is focused into a high-intensity spot. L film 1430 may only allow light of a certain linear polarization state to pass through. Thus, about 50% or more of the ambient light (e.g., unpolarized light) may be blocked and prevented from reaching LCD display panel 1410. Therefore, the intensity of the ambient light focused onto LCD display panel 1410 (e.g., color filter layer 1422, or LC cell 1418) may only be a half or lower of the intensity of the ambient light focused onto LCD display panel 1410 when L film 1430 is not used. Even though FIG. 14 shows that L film 1430 may be laminated onto the front surface of cover window 1420, in other embodiments, L film 1430 may also be laminated onto the rear surface of cover window 1420 or another structure between display optics 1440 and LCD display panel 1410.

FIGS. 15A-15B illustrate examples of using L films and/or infrared blocking layers to avoid damages to display panels by bright ambient light according to certain embodiments. In some embodiments, an infrared blocking layer may be used in combination with an L film. In the example shown in FIG. 15A, an infrared blocking coating 1520 may be coated on an L film 1510, which may be laminated onto a surface of the display optics, cover window, or lens adaptor/cover as described above with respect to, for example, FIGS. 11A-11C. Infrared blocking coating 1520 may block, for example, about 50% of infrared light, thereby further reducing the intensity of the ambient light that may be focused onto the display panel and the amount of heat absorbed by the display panel.

In the example shown in FIG. 15B, an infrared blocking optically clear adhesive 1550 may be used to bond an L film 1540 to a substrate 1530, such as the display optics, cover window, or lens adaptor/cover described above with respect to, for example, FIGS. 11A-11C. Infrared blocking optically clear adhesive 1550 may block, for example, about 50% of infrared light, thereby further reducing the intensity of the ambient light that may be focused onto the display panel and the amount of heat absorbed by the display panel.

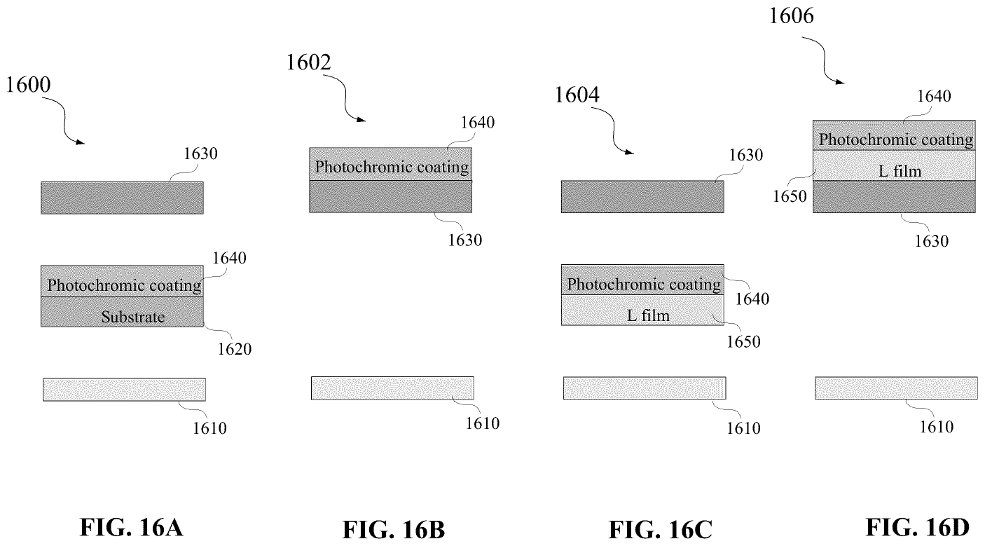

FIGS. 16A-16D illustrate examples of using photochromic (and UV blocking) coatings to avoid damages to display panels by bright ambient light according to certain embodiments. Photochromic (and UV blocking) coating may be added on any lens; any structure between display optics and the display panel before ambient light is focused into a small, high-intensity spot; any linear polarizer coupled to the display optics, cover window, or lens adaptor/cover; or any L film formed on the display optics, cover window, or lens adaptor/cover.

In the example shown in FIG. 16A, a near-eye display system 1600 may include a display panel 1610, display optics 1630, and one or more spacers between display panel 1610 and display optics 1630, such that display panel 1610 may be at or near a focal plane of display optics 1630. Near-eye display system 1600 may also include a substrate 1620 (e.g., cover window) between display panel 1610 and display optics 1630. A photochromic (and UV blocking) coating 1640 may be formed on substrate 1620. When bright ambient light is incident on photochromic coating 1640, photochromic coating 1640 may absorb light and become darker, and thus may have a lower transmissivity to reduce the intensity of the light incident on display panel 1610.

In the example shown in FIG. 16B, a near-eye display system 1602 may include display panel 1610, display optics 1630, and a spacer between display panel 1610 and display optics 1630, such that display panel 1610 may be at or near a focal plane of display optics 1630. Near-eye display system 1600 may also include photochromic (and UV blocking) coating 1640 formed on front or rear surface of display optics 1630. When bright ambient light is incident on photochromic (and UV blocking) coating 1640, photochromic (and UV blocking) coating 1640 may absorb light and become darker, and thus may have a lower transmissivity to reduce the intensity of the light incident on display panel 1610.

In the example shown in FIG. 16C, a near-eye display system 1604 may include display panel 1610, display optics 1630, and one or more spacers between display panel 1610 and display optics 1630, such that display panel 1610 may be at or near a focal plane of display optics 1630. Near-eye display system 1600 may also include an L film 1650 formed on a substrate (e.g., cover window) between display panel 1610 and display optics 1630. Photochromic (and UV blocking) coating 1640 may be formed on L film 1650. In some embodiments, photochromic coating 1640 may be formed on the substrate, and L film 1650 may be formed on photochromic coating 1640. In some embodiments, L film 1650 and photochromic coating 1640 may be formed on opposite surfaces of a substrate. When bright ambient light is incident on photochromic coating 1640, photochromic coating 1640 may absorb light and become darker, and thus may have a lower transmissivity to reduce the intensity of the light incident on display panel 1610.

In the example shown in FIG. 16D, a near-eye display system 1606 may include display panel 1610, display optics 1630, and a spacer between display panel 1610 and display optics 1630, such that display panel 1610 may be at or near a focal plane of display optics 1630. Near-eye display system 1600 may also include an L film 1650 formed on a surface of display optics 1630. Photochromic (and UV blocking) coating 1640 may be formed on L film 1650. In some embodiments, photochromic coating 1640 may be formed on display optics 1630, and L film 1650 may be formed on photochromic coating 1640. In some embodiments, L film 1650 and photochromic coating 1640 may be formed on opposite surfaces of display optics 1630. When bright ambient light is incident on photochromic coating 1640, photochromic coating 1640 may absorb light and become darker, and thus may have a lower transmissivity to reduce the intensity of the light incident on display panel 1610.

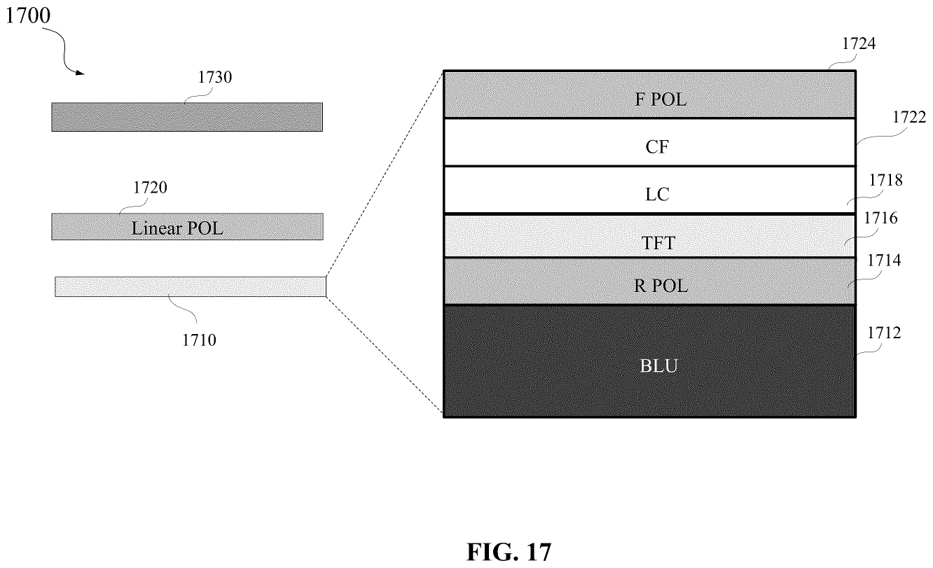

FIG. 17 illustrates an example of a near-eye display system 1700 including a reflective linear polarizer 1720 to avoid damages to an LCD display panel 1710 by bright ambient light according to certain embodiments. In the example illustrated in FIG. 17, near-eye display system 1700 may include an LCD display panel 1710 that may include a layer stack as described above with respect to, for example, FIG. 11A. LCD display panel 1710 may include a backlight unit 1712, a rear polarizer 1714, a TFT layer 1716, an LC cell 1718, a color filter layer 1722, and a front polarizer 1724. Front polarizer 1724 may be aligned with rear polarizer 1714. Display optics 1730 may include a lens, such as a Fresnel lens. Display optics 1730 may be separated from LCD display panel 1710 by one or more spacers, such that the focal plane of display optics 1730 may be at or near LCD display panel 1710. A linear polarizer 1720 may be positioned on display optics 1730, between display optics 1730 and LCD display panel 1710, or between display optics 1730 and ambient environment. The transmission axis of linear polarizer 1720 may align with the transmission axis of front polarizer 1724. Either one or both linear polarizer 1720 and front polarizer 1724 may be reflective polarizers, such as wire grid reflective polarizers which may transmit light with an electric field vector perpendicular to the wire and reflect light with the electric field-vector parallel to the wire.

In the example shown in FIG. 17, ambient light from, for example, the sun, may be modified by display optics 1730 and filtered by linear polarizer 1720 before the ambient light is focused into a high-intensity spot on LCD display panel 1710. Linear polarizer 1720 may only allow light of a certain linear polarization state to pass through and may reflect light of the orthogonal linear polarization state. About 50% or more of the ambient light (e.g., unpolarized light) may be blocked and prevented from reaching LCD display panel 1710. Therefore, the intensity of the ambient light focused onto LCD display panel 1710 (e.g., front polarizer 1724, color filter layer 1722, or LC cell 1718) may only be a half or lower of the intensity of the ambient light focused onto LCD display panel 1710 when linear polarizer 1720 is not used. The transmission axis of linear polarizer 1720 may align with the transmission axis of front polarizer 1724, such that the addition of linear polarizer 1720 may cause minimum or no additional loss of the display light from LCD display panel 1710 when near-eye display system 1700 is in normal operation. In addition, light passing through linear polarizer 1720 may be mostly transmitted and may not be absorbed by front polarizer 1724 because the polarization direction of the incident light aligns with the transmission axis of front polarizer 1724. Therefore, front polarizer 1724 may not be damaged by the ambient light.

As described above, in some implementations, to relax the requirement of aligning linear polarizer 1720 with front polarizer 1724, a pair of quarter wave plates may be used to convert linearly polarized light from linear polarizer 1720 (or from front polarizer 1724 of LCD display panel 1710) into circularly polarized light, and convert the circularly polarized light back to linearly polarized light that may pass through front polarizer 1724 (or linear polarizer 1720).

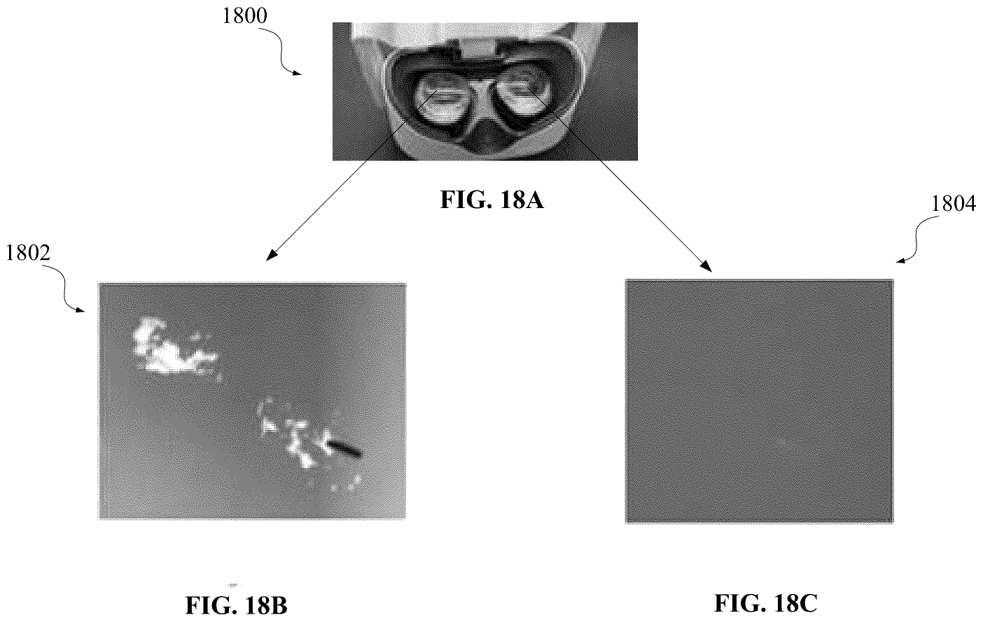

FIGS. 18A-18C illustrate an example of reducing damages to a display panel of a near-eye display system by bright ambient light using techniques disclosed herein according to certain embodiments. FIG. 18A shows an example of a near-eye display system 1800 for virtual reality application. Near-eye display system 1800 may include one LCD display panel for both eyes, or may include two LCD display panels each for one eye. In the illustrated near-eye display system 1800, the left side of near-eye display system 1800 may not implement techniques disclosed herein, while the right side of near-eye display system 1800 may implement one of the techniques disclosed herein. FIG. 18B shows an image 1802 of the left side of the LCD display panel, which shows damages on the left side of the LCD display panel caused by sunlight focused onto the LCD display panel. FIG. 18C shows an image 1804 of the right side of the LCD display panel, which shows that there are no damages on the right side of the LCD display panel caused by sunlight.

Techniques disclosed herein may also be used in other types of near-eye display systems. For example, the polarization film, IR blocking coating, IR blocking optically clear adhesive layer, photochromic (or UV blocking) coating, another optical attenuation film, or any combination thereof may be used in OLED-based near-eye display systems to reduce sun damage. In some embodiments, the polarization film, IR blocking coating, IR blocking optically clear adhesive layer, photochromic (or UV blocking) coating, another optical attenuation film, or any combination thereof may be used in an accessory device of a near-eye display, such as a prescription lens used in a near-eye display.

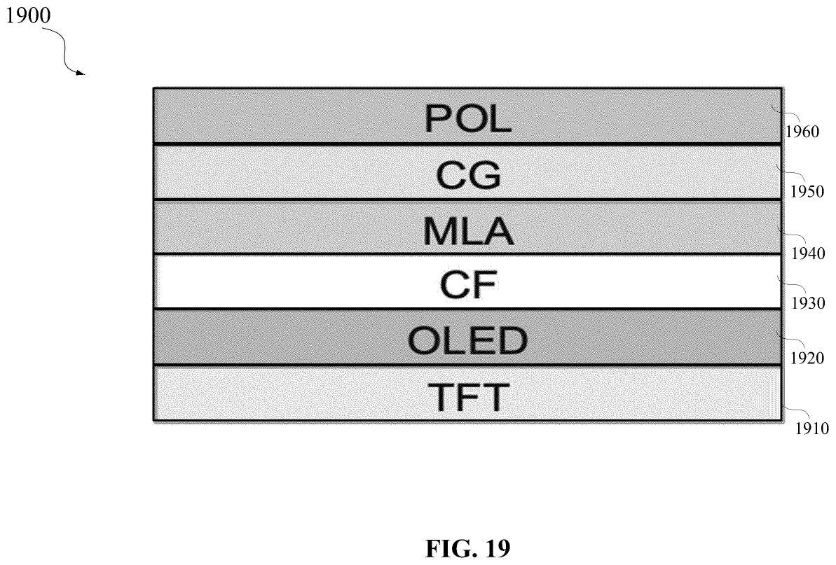

FIG. 19 illustrates an example of a micro-OLED display 1900 that may implement some of the examples disclosed herein according to certain embodiments. In the illustrated example, micro-OLED display 1900 may include a thin-film transistor (TFT) layer 1910, an organic LED (OLED) layer 1920, a color filter layer 1930, a micro-lens array (MLA) 1940, a cover glass (CG) 1950, and a polarizer 1960. TFT layer 1910 may include control circuits for controlling individual OLEDs. OLED layer 1920 may include, for example, a hole injection layer, a hole transport layer, an emissive layer, an electron transport layer, and an electron injection layer. Color filter layer 1930 may include an array of color filters (e.g., red, green, and blue filters) that may allow light in certain color ranges to pass through to form color pixels for displaying color images. MLA 1940 may include an array of micro-lenses and may be used to collimate light emitted in the OLED layer 1920. Cover glass 1950 may be used to support and protect other components of micro-OLED display 1900. Polarizer 1960 may include an antireflective polarizer for reducing the reflection of ambient light to user's eye. For example, the antireflective polarizer may include a linear polarizer and a quarterwave plate. In some embodiments, polarizer 1960 may also include an IR blocking coating, an IR blocking optically clear adhesive layer, a photochromic (or UV blocking) coating, another optical attenuation film, or any combination thereof, to attenuate ambient light (e.g., sunlight), such that ambient light that may pass through polarizer 1960 and reach other layers of micro-OLED display 1900 may be attenuated and may not damage the other layers of micro-OLED display 1900. As described above, the optical attenuation film(s) may be formed on a surface of a layer of micro-OLED display 1900, such as cover glass 1950 or polarizer 1960, or may be formed on an additional substrate that is coupled to or spaced apart from a layer of micro-OLED display 1900.

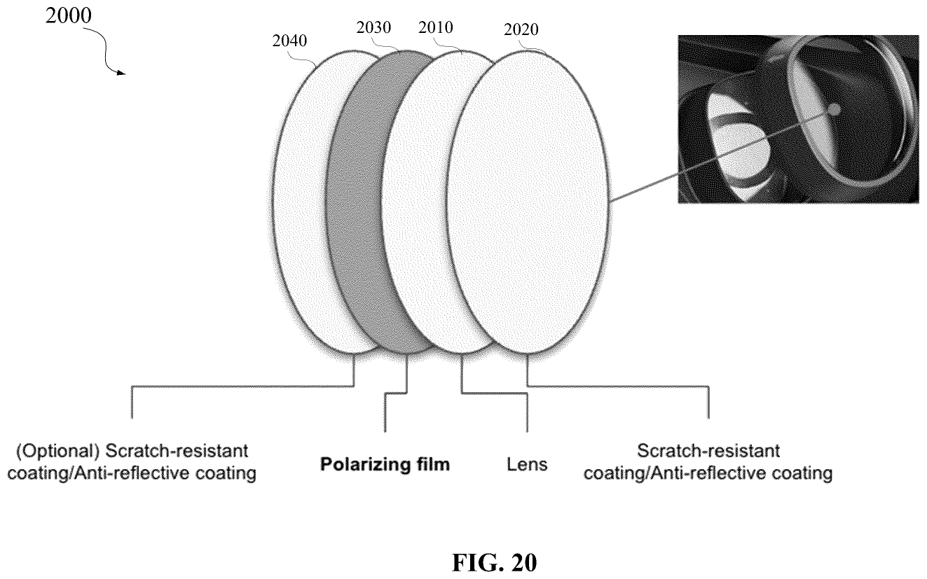

FIG. 20 illustrate an example of a prescription lens 2000 that may implement some of the examples disclosed herein according to certain embodiments. In the illustrated example, prescription lens 2000 may include a lens 2010 made of, for example, glass, polycarbonate, or high-index plastics. Lens 2010 may be a prescription lens for correcting deficiencies of user's eyes. A scratch-resistant coating and/or antireflective coating layer 2020 may be formed on one side of lens 2010. An optical attenuation layer 2030, such as a polarizing film, an IR blocking coating, an IR blocking optically clear adhesive layer, a photochromic (or UV blocking) coating, another optical attenuation film, or any combination thereof, may be formed on another side of lens 2010. An optional scratch-resistant coating and/or antireflective coating layer 2040 may be formed on a side of optical attenuation layer 2030 opposing lens 2010.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

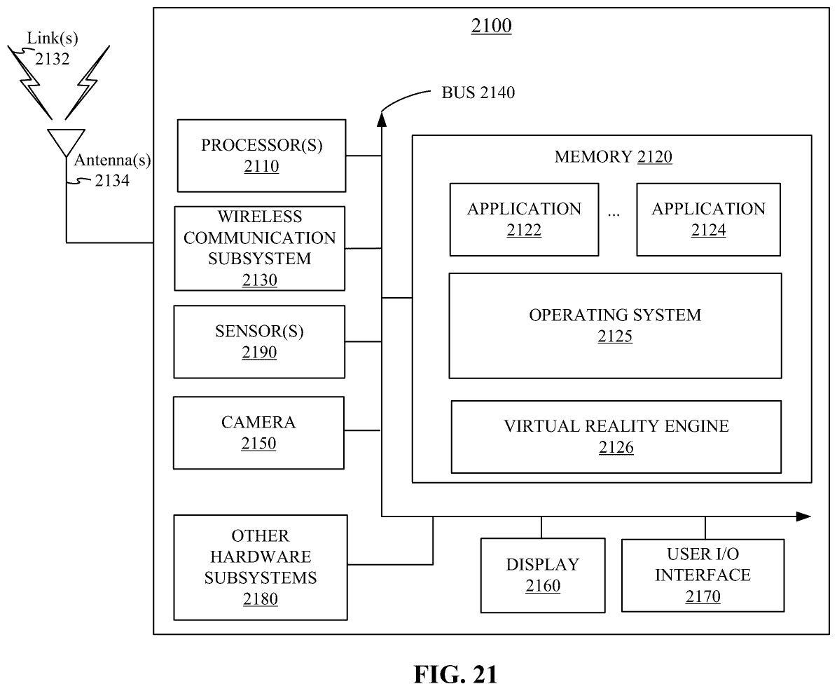

FIG. 21 is a simplified block diagram of an example of an electronic system 2100 of an example near-eye display (e.g., HMD device) for implementing some examples disclosed herein. Electronic system 2100 may be used as the electronic system of an HMD device or other near-eye displays described above. In this example, electronic system 2100 may include one or more processor(s) 2110 and a memory 2120. Processor(s) 2110 may be configured to execute instructions for performing operations at a number of components, and can be, for example, a general-purpose processor or microprocessor suitable for implementation within a portable electronic device. Processor(s) 2110 may be communicatively coupled with a plurality of components within electronic system 2100. To realize this communicative coupling, processor(s) 2110 may communicate with the other illustrated components across a bus 2140. Bus 2140 may be any subsystem adapted to transfer data within electronic system 2100. Bus 2140 may include a plurality of computer buses and additional circuitry to transfer data.

Memory 2120 may be coupled to processor(s) 2110. In some embodiments, memory 2120 may offer both short-term and long-term storage and may be divided into several units. Memory 2120 may be volatile, such as static random access memory (SRAM) and/or dynamic random access memory (DRAM) and/or non-volatile, such as read-only memory (ROM), flash memory, and the like. Furthermore, memory 2120 may include removable storage devices, such as secure digital (SD) cards. Memory 2120 may provide storage of computer-readable instructions, data structures, program code, and other data for electronic system 2100. In some embodiments, memory 2120 may be distributed into different hardware subsystems. A set of instructions and/or code might be stored on memory 2120. The instructions might take the form of executable code that may be executable by electronic system 2100, and/or might take the form of source and/or installable code, which, upon compilation and/or installation on electronic system 2100 (e.g., using any of a variety of generally available compilers, installation programs, compression/decompression utilities, etc.), may take the form of executable code.

In some embodiments, memory 2120 may store a plurality of applications 2122 through 2124, which may include any number of applications. Examples of applications may include gaming applications, conferencing applications, video playback applications, or other suitable applications. The applications may include a depth sensing function or eye tracking function. Applications 2122-2124 may include particular instructions to be executed by processor(s) 2110. In some embodiments, certain applications or parts of applications 2122-2124 may be executable by other hardware subsystems 2180. In certain embodiments, memory 2120 may additionally include secure memory, which may include additional security controls to prevent copying or other unauthorized access to secure information.

In some embodiments, memory 2120 may include an operating system 2125 loaded therein. Operating system 2125 may be operable to initiate the execution of the instructions provided by applications 2122-2124 and/or manage other hardware subsystems 2180 as well as interfaces with a wireless communication subsystem 2130 which may include one or more wireless transceivers. Operating system 2125 may be adapted to perform other operations across the components of electronic system 2100 including threading, resource management, data storage control and other similar functionality.

Wireless communication subsystem 2130 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 2100 may include one or more antennas 2134 for wireless communication as part of wireless communication subsystem 2130 or as a separate component coupled to any portion of the system. Depending on desired functionality, wireless communication subsystem 2130 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 2130 may permit data to be exchanged with a network, other computer systems, and/or any other devices described herein. Wireless communication subsystem 2130 may include a means for transmitting or receiving data, such as identifiers of HMD devices, position data, a geographic map, a heat map, photos, or videos, using antenna(s) 2134 and wireless link(s) 2132.

Embodiments of electronic system 2100 may also include one or more sensors 2190. Sensor(s) 2190 may include, for example, an image sensor, an accelerometer, a pressure sensor, a temperature sensor, a proximity sensor, a magnetometer, a gyroscope, an inertial sensor (e.g., a subsystem that combines an accelerometer and a gyroscope), an ambient light sensor, or any other similar devices or subsystems operable to provide sensory output and/or receive sensory input, such as a depth sensor or a position sensor. For example, in some implementations, sensor(s) 2190 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or some combination thereof. The position sensors may be located external to the IMU, internal to the IMU, or some combination thereof. At least some sensors may use a structured light pattern for sensing.

Electronic system 2100 may include a display 2160. Display 2160 may be a near-eye display, and may graphically present information, such as images, videos, and various instructions, from electronic system 2100 to a user. Such information may be derived from one or more applications 2122-2124, virtual reality engine 2126, one or more other hardware subsystems 2180, a combination thereof, or any other suitable means for resolving graphical content for the user (e.g., by operating system 2125). Display 2160 may use liquid crystal display (LCD) technology, light-emitting diode (LED) technology (including, for example, OLED, ILED, μLED, AMOLED, TOLED, etc.), light emitting polymer display (LPD) technology, or some other display technology.

Electronic system 2100 may include a user input/output interface 2170. User input/output interface 2170 may allow a user to send action requests to electronic system 2100. An action request may be a request to perform a particular action. For example, an action request may be to start or end an application or to perform a particular action within the application. User input/output interface 2170 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 2100. In some embodiments, user input/output interface 2170 may provide haptic feedback to the user in accordance with instructions received from electronic system 2100. For example, the haptic feedback may be provided when an action request is received or has been performed.

Electronic system 2100 may include a camera 2150 that may be used to take photos or videos of a user, for example, for tracking the user's eye position. Camera 2150 may also be used to take photos or videos of the environment, for example, for VR, AR, or MR applications. Camera 2150 may include, for example, a complementary metal-oxide-semiconductor (CMOS) image sensor with a few millions or tens of millions of pixels. In some implementations, camera 2150 may include two or more cameras that may be used to capture 3-D images.

In some embodiments, electronic system 2100 may include a plurality of other hardware subsystems 2180. Each of other hardware subsystems 2180 may be a physical subsystem within electronic system 2100. While each of other hardware subsystems 2180 may be permanently configured as a structure, some of other hardware subsystems 2180 may be temporarily configured to perform specific functions or temporarily activated. Examples of other hardware subsystems 2180 may include, for example, an audio output and/or input interface (e.g., a microphone or speaker), a near field communication (NFC) device, a rechargeable battery, a battery management system, a wired/wireless battery charging system, etc. In some embodiments, one or more functions of other hardware subsystems 2180 may be implemented in software.

In some embodiments, memory 2120 of electronic system 2100 may also store a virtual reality engine 2126. Virtual reality engine 2126 may execute applications within electronic system 2100 and receive position information, acceleration information, velocity information, predicted future positions, or some combination thereof of the HMD device from the various sensors. In some embodiments, the information received by virtual reality engine 2126 may be used for producing a signal (e.g., display instructions) to display 2160. For example, if the received information indicates that the user has looked to the left, virtual reality engine 2126 may generate content for the HMD device that mirrors the user's movement in a virtual environment. Additionally, virtual reality engine 2126 may perform an action within an application in response to an action request received from user input/output interface 2170 and provide feedback to the user. The provided feedback may be visual, audible, or haptic feedback. In some implementations, processor(s) 2110 may include one or more GPUs that may execute virtual reality engine 2126.

In various implementations, the above-described hardware and subsystems may be implemented on a single device or on multiple devices that can communicate with one another using wired or wireless connections. For example, in some implementations, some components or subsystems, such as GPUs, virtual reality engine 2126, and applications (e.g., tracking application), may be implemented on a console separate from the head-mounted display device. In some implementations, one console may be connected to or support more than one HMD.

In alternative configurations, different and/or additional components may be included in electronic system 2100. Similarly, functionality of one or more of the components can be distributed among the components in a manner different from the manner described above. For example, in some embodiments, electronic system 2100 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

In this description, unless otherwise stated, “about,” “approximately” or “substantially” preceding a parameter means being within +/−10 percent of that parameter or, if the parameter is zero, a reasonable range of values around zero. Also, in this description, the recitation “based on” means “based at least in part on.” Therefore, if X is based on Y, then X may be a function of at least a part of Y and any number of other factors. If an action X is “based on” Y, then the action X may be based at least in part on at least a part of Y.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or any combination of A, B, and/or C, such as AB, AC, BC, AA, ABC, AAB, AABBCCC, or the like.

In this description, the recitation “based on” means “based at least in part on.” Therefore, if X is based on Y, then X may be a function of at least a part of Y and any number of other factors. If an action X is “based on” Y, then the action X may be based at least in part on at least a part of Y.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different time.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A near-eye display system comprising:
a liquid crystal display (LCD) panel configured to generate a display image, the LCD panel comprising:
a backlight unit configured to emit visible light;
a first linear polarizer configured to linearly polarize the visible light emitted by the backlight unit; and
a liquid crystal cell;
display optics configured to project the display image to a user; and
a second linear polarizer, wherein the second linear polarizer is:
formed on the display optics;
between the display optics and the LCD panel and spaced apart from the LCD panel; or
on a side of the display optics opposing the LCD panel,
wherein a transmission axis of the second linear polarizer is parallel to a transmission axis of the first linear polarizer.

2. The near-eye display system of claim 1, wherein the first linear polarizer is the only linear polarizer between the second linear polarizer and the backlight unit.

3. The near-eye display system of claim 1, wherein the second linear polarizer includes a polarizer film laminated or coated on a surface of:
the display optics;
a substrate between the display optics and the LCD panel and spaced apart from the LCD pane; or
a substrate on the side of the display optics opposing the LCD panel.

4. The near-eye display system of claim 1, wherein the second linear polarizer comprises:
an iodine based polyvinyl alcohol (PVA) absorptive polarizer;
a non-iodine based PVA absorptive polarizer; or
a wire grid reflective polarizer.

5. The near-eye display system of claim 1, wherein:
the LCD panel further comprises a third linear polarizer on the side of the liquid crystal cell opposing the first linear polarizer; and
a transmission axis of the third linear polarizer is parallel to the transmission axis of the second linear polarizer.

6. The near-eye display system of claim 5, further comprising a pair of quarter wave plates between the second linear polarizer and the third linear polarizer.

7. The near-eye display system of claim 5, wherein the third linear polarizer includes a reflective linear polarizer.

8. The near-eye display system of claim 1, wherein the second linear polarizer is on a cover window between the display optics and the LCD panel.

9. The near-eye display system of claim 1, wherein the second linear polarizer is on a lens cover.

10. The near-eye display system of claim 1, further comprising one or more spacers between the display optics and the LCD panel such that the LCD panel is at or near a focal plane of the display optics.

11. The near-eye display system of claim 1, further comprising an infrared blocking layer on the second linear polarizer.

12. The near-eye display system of claim 1, further comprising a photochromic layer on the second linear polarizer.

13. The near-eye display system of claim 1, further comprising an infrared blocking layer on a surface of:
the display optics;
a substrate between the display optics and the LCD panel and spaced apart from the LCD pane; or
a substrate on the side of the display optics opposing the LCD panel.

14. The near-eye display system of claim 1, further comprising a photochromic layer on a surface of:
the display optics;
a substrate between the display optics and the LCD panel and spaced apart from the LCD pane; or
a substrate on the side of the display optics opposing the LCD panel.

15. The near-eye display system of claim 1, wherein the LCD panel includes a thin-film transistor drive circuit layer between the first linear polarizer and the liquid crystal cell.

16. The near-eye display system of claim 1, wherein the display optics include a Fresnel lens or a lens assembly.

17. A near-eye display system comprising:
a liquid crystal display (LCD) panel comprising:
a backlight unit configured to emit visible light;
a first linear polarizer configured to linearly polarize the visible light emitted by the backlight unit; and
a liquid crystal cell;
display optics spaced apart from the LCD panel; and
a second linear polarizer, wherein the second linear polarizer is:
formed on the display optics;
between the display optics and the LCD panel and spaced apart from the LCD panel; or
on a side of the display optics opposing the LCD panel,
wherein a transmission axis of the second linear polarizer is parallel to a transmission axis of the first linear polarizer, and
wherein the first linear polarizer is the only linear polarizer between the second linear polarizer and the backlight unit.

18. The near-eye display system of claim 17, wherein the second linear polarizer includes a polarizer film laminated or coated on a surface of:
the display optics;
a substrate between the display optics and the LCD panel and spaced apart from the LCD pane; or
a substrate on the side of the display optics opposing the LCD panel.

19. A near-eye display system comprising:
a liquid crystal display (LCD) panel configured to generate a display image, the LCD panel comprising:
a backlight unit configured to emit visible light;
a first linear polarizer configured to linearly polarize the visible light emitted by the backlight unit;
a liquid crystal cell;
a color filter layer on one side of the liquid crystal cell; and
a second linear polarizer on a side of the liquid crystal cell opposing the first linear polarizer, wherein a transmission axis of the second linear polarizer is parallel to a transmission axis of the first linear polarizer;
display optics configured to project the display image to a user; and
a third linear polarizer, wherein the third linear polarizer is positioned:
on the display optics;
between the display optics and the LCD panel and spaced apart from the LCD panel; or
on a side of the display optics opposing the LCD panel,
wherein a transmission axis of the third linear polarizer is parallel to the transmission axis of the second linear polarizer.

20. The near-eye display system of claim 19, wherein the third linear polarizer includes a polarizer film laminated or coated on a surface of:
the display optics;
a substrate between the display optics and the LCD panel and spaced apart from the LCD pane; or
a substrate on the side of the display optics opposing the LCD panel.
